(19) United States
(12) Patent Application Publication
(10) Pub. No.: US 2024/0310887 A1
(43) Pub. Date: Sep. 19, 2024

(54) Smart Start-up Detection Circuit for Multi-VIO System

(71) Applicant: QUALCOMM Incorporated, San Diego, CA (US)

(72) Inventors: Xingyi HUA, San Diego, CA (US); David Zixiang YANG, San Diego, CA (US); Francesco GATTA, San Diego, CA (US)

(21) Appl. No.: 18/121,508

(22) Filed: Mar. 14, 2023

(51) Int. Cl. G06F 1/26; H04M 1/725

(52) U.S. Cl. CPC G06F 1/26; H04M 1/725; H04M 2201/02; H04M 2201/04; H04M 2201/06; H04M 2201/14

(57) ABSTRACT

A dual-VIO integrated circuit is configurable into either a first configuration in which a VIO power supply voltage has a first value or into a second configuration in which the VIO power supply voltage has a second value. The dual-VIO integrated circuit includes a smart start-up detection circuit that detects whether the integrated circuit is in the first configuration or the second configuration.

### TECHNICAL FIELD

This application relates to start-up for an integrated circuit, and more particularly to a start-up voltage detection circuit for a multi-VIO system.

### BACKGROUND

As compared to the core digital power domain of an integrated circuit, the input/output (IO) power domain often uses a higher voltage for a power supply voltage (VIO) due to the continuing presence of legacy input/output protocols. The specification for the VIO power supply voltage depends upon the particular input/output protocol selected for an integrated circuit and may thus vary accordingly. Commonly-used values for the VIO power supply voltage include 1.2 V and 1.8V, which may be designated as the low VIO (VIO_{L}) and the high VIO (VIO_{H}), respectively.

The varying levels for the VIO power supply voltage present an issue to the integrated circuit designer. For example, the IO circuitry associated with an IO pin or terminal typically includes analog or digital circuitry that is sensitive to the VIO power supply voltage level. Some examples of such circuitry include a clock source (oscillator) having a frequency that varies depending upon the VIO power supply magnitude. To identify the VIO power supply voltage, an integrated circuit could dedicate an IO pin or terminal. By receiving a VIO identification signal over such a pin, the integrated circuit may identify which of the two VIO power supply voltages is being implemented. But this dedicated pin increases manufacturing cost and complexity. Alternatively, software in the integrated circuit may be programmed with the selected VIO level. But software programming can only be performed after VIO is stable, which still leaves the VIO identification signal undefined before the software programming, which may cause issues during start-up. As yet another alternative, a fuse memory could be programmed to identify the selected VIO level. But just like the software programming, the fuse memory programming takes place after VIO is stable, which again leaves the VIO identification signal undefined before the programming. Moreover, these approaches also increase manufacturing cost and complexity analogously to the use of a dedicated pin.

### SUMMARY

In accordance with an aspect of the disclosure, an integrated circuit is provided that includes: a delay circuit configured to assert a delay circuit output signal after an expiration of a delay period following an assertion of a power-on reset signal during a power-on of the integrated circuit; a pulse circuit configured to pulse an enable signal in response to the expiration of the delay period; and a voltage detection circuit configured to detect, during the pulse of the enable signal, whether a power supply voltage of the integrated circuit is regulated to equal a first value or regulated to equal a second value that is larger than the first value.

In accordance with another aspect of the disclosure, a method of detecting a power supply voltage configuration is provided that includes: initiating a delay period in response to an assertion of a power-on-reset signal during a power-up of an integrated circuit; pulsing an enable signal in response to a termination of the delay period; and detecting, while the enable signal is pulsed, whether a power domain of the integrated circuit is configured into a first configuration in which a power supply voltage of the power domain is regulated to a first value or into a second configuration in which the power supply voltage is regulated to a second value that is greater than the first value.

In accordance with yet another aspect of the disclosure, a multi-voltage input/output (VIO) integrated circuit is provided that includes: a delay circuit configured to delay a power-on reset signal to produce a delayed version of the power-on reset signal; and a VIO detection circuit configured to assert a VIO detection signal responsive to a power supply voltage of a VIO power domain in the integrated circuit being greater than a threshold voltage.

These and other advantageous features may be better appreciated through the following detailed description.

### BRIEF DESCRIPTION OF THE DRAWINGS

FIG. 1 is a circuit diagram of smart start-up VIO detection circuit for a dual-VIO integrated circuit in accordance with an aspect of the disclosure.

FIG. 2 is a circuit diagram of an example implementation of the pulse generator in the start-up VIO detection circuit of FIG. 1 in accordance with an aspect of the disclosure.

FIG. 3 is a circuit diagram of an example implementation of the VIO detection circuit in the start-up VIO detection circuit of FIG. 1 in accordance with an aspect of the disclosure.

FIG. 4 is flow chart of a power supply voltage detection method in accordance with an aspect of the disclosure.

FIG. 5 illustrates some example electronic systems including an integrated circuit having a smart start-up VIO detection circuit in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

A multi-VIO integrated circuit is configured to use one of a plurality of possible VIO power supply voltage levels. To identify the particular VIO power supply level at start-up of a multi-VIO integrated circuit, a smart start-up VIO detection circuit is provided that eliminates the need for a dedicated pin or fuse memory. The following discussion is directed to a smart start-up VIO detection circuit for a dual-VIO integrated circuit but it will be appreciated a smart start-up VIO detection circuit for a dual-VIO integrated circuit is readily adapted for use in multi-VIO integrated circuits that are configured to use three or more possible VIO power supply voltage levels.

In a dual-VIO integrated circuit, the lower VIO power supply voltage may be denoted as VIO_{L} or the low VIO level whereas the greater VIO power supply voltage may be denoted as VIO_{H} or the high VIO level. Should the start-up VIO detection circuit detect that the VIO power supply voltage corresponds to the high VIO level, the start-up VIO detection circuit asserts a VIO detection signal. As defined herein, a binary signal such as the VIO detection signal is deemed to be asserted when the signal is true, regardless of whether an active-high or an active-low convention is used. In an active-high convention, an asserted signal is asserted to a power supply voltage. Conversely, an asserted signal is discharged to ground in an active-low convention.

With regard to the VIO detection, the smart start-up VIO detection circuit responds to an assertion of a power-on reset (POR) signal at the power-up of the dual-VIO integrated circuit to begin a delay period to allow the VIO power supply voltage to sufficiently settle. At the expiration of the delay period, the smart start-up VIO detection circuit detects the VIO level and asserts (or de-asserts) the VIO detection signal accordingly. The following discussion will assume that the dual-VIO integrated circuit operates according to the Mobile Industry Processor Interface (MiPi) standards such that the maximum ramp-up period for the VIO power supply voltage at power-up of the dual-VIO integrated circuit is 400 μs. However, it will be appreciated that the smart start-up VIO detection circuit disclosed herein is readily adaptable to VIO ramp-up times that are greater or smaller than this MiPi standard ramp-up time.

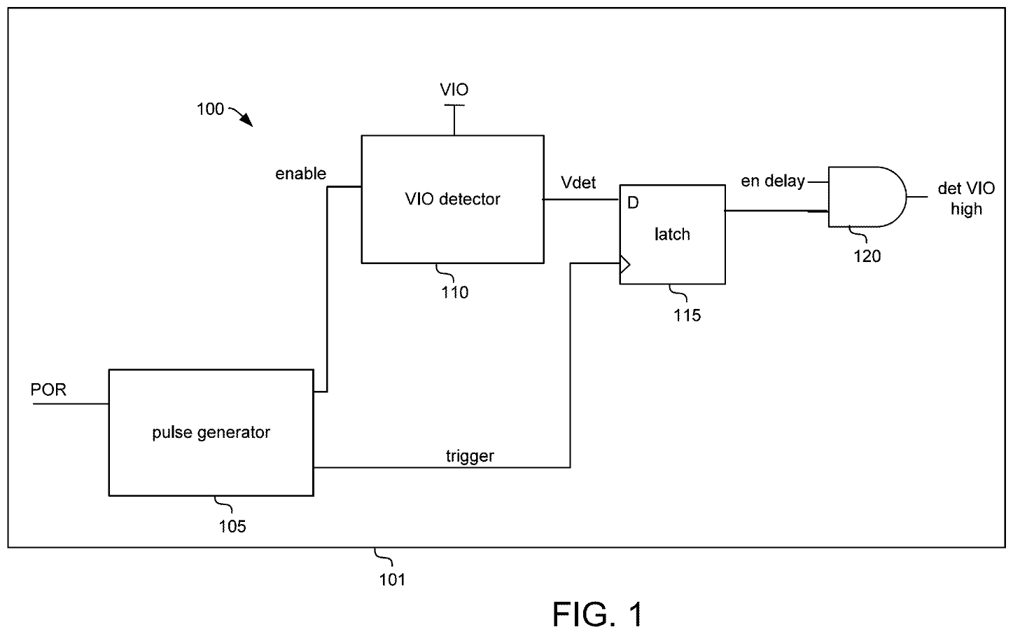

An example start-up VIO detection circuit 100 is shown in FIG. 1 for the detection of the VIO power supply voltage level in a dual-VIO integrated circuit 101. A pulse generator 105 in the VIO detection circuit 100 responds to the assertion of the POR signal by beginning the delay period and then pulsing an enable signal at the expiration of the delay period. Given the MiPi ramp-up time of 400 μs, a suitable delay period may be greater than this ramp-up time to allow the VIO power supply voltage to sufficiently settle. The length of the delay period in some example implementations may thus range from approximately 500 μs to 1.3 ms. While the enable signal is asserted, a VIO detector circuit 110 functions to detect the level of the VIO power supply voltage. While the enable signal is not pulsed, the VIO detector circuit 110 is disabled so that it does not consume power. The pulse generator 105 provides a sufficient pulse width to the enable signal so that the VIO detector circuit 110 can detect the VIO power supply voltage level. In the following discussion, it will be assumed that the enable signal pulse width is 3 μs, but it will be appreciated that this pulse width may be greater or smaller in alternative implementations.

The VIO detector circuit 110 asserts a binary VIO detection signal Vdet to the VIO power supply voltage should the dual-VIO integrated circuit 101 be configured to regulate the VIO power supply voltage to the high level. However, an active-low convention for the binary detection signal Vdet may be used in alternative implementations. Should the dual-VIO integrated circuit 101 be configured to regulate the VIO power supply voltage to equal the low level, VIO detector circuit 110 de-asserts (discharges) the binary detection signal Vdet in an active-high implementation. At the end of the enable signal pulse width, a latch 115 is clocked by the pulse generator 105 to latch the binary detection signal Vdet. For example, the pulse generator 105 may pulse a trigger signal to clock the latch 115. A logic gate such as an AND gate 120 processes a latch output signal from the latch 115 with an enable delay signal (en delay) that is asserted during the operation of the VIO detection circuit 100. An output signal (det VIO high) of the AND gate 120 will thus be asserted if the VIO power supply voltage is detected to be at the high level. Conversely, the det VIO high signal will be discharged if the VIO power supply voltage is detected to be at the low level. Additional circuitry (not illustrated) in the dual-VIO integrated circuit 101 may then respond to the det VIO high signal accordingly. For example, the integrated circuit 101 may adjust an operating parameter such as by adjusting an oscillator frequency responsive to the det VIO high signal. Similarly, the integrated circuit 101 may adjust a digital circuit timing responsive to the det VIO high signal and so on.

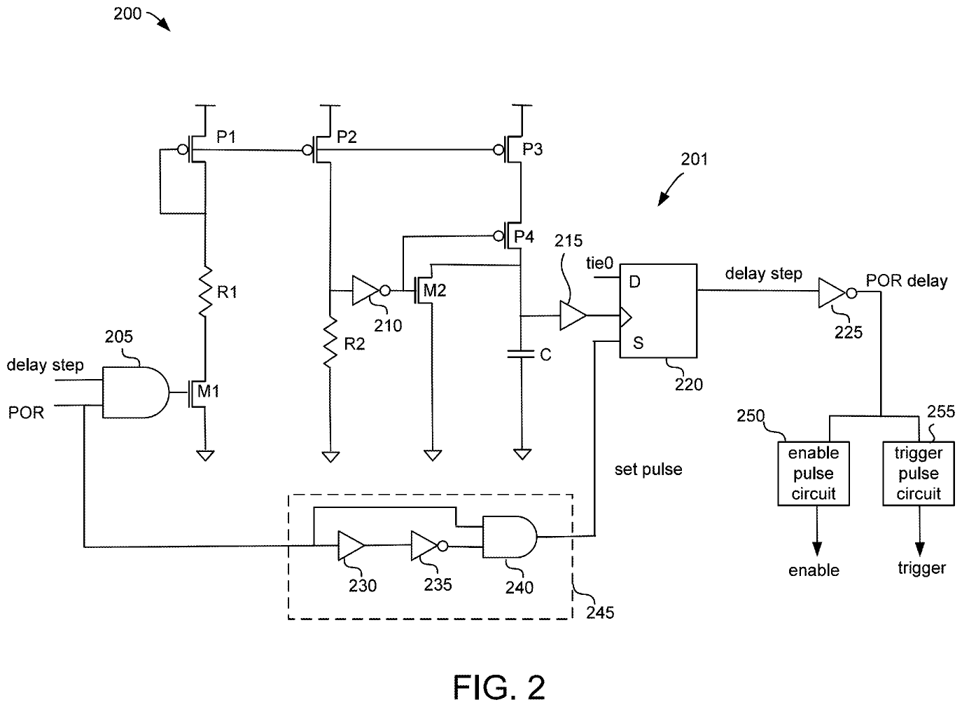

An example implementation 200 of the pulse generator 105 is shown in FIG. 2. Pulse generator 200 includes a delay circuit 201 configured to assert a POR delay signal at the expiration of the delay period following the assertion of the POR signal. To respond to the assertion of the POR signal, a logic gate such as an AND gate 205 ANDs the POR signal with a delay step signal that will be discussed further herein. While both the POR signal and the delay step signal are asserted, the AND gate 205 switches on an n-type metal-oxide semiconductor (NMOS) transistor M1 that has a source coupled to ground. Transistor M1 may also be denoted as a first transistor. A source of the transistor M1 couples to ground whereas its drain couples through a resistor R1 to a drain of a diode-connected p-type metal-oxide semiconductor (PMOS) transistor P1 having a source coupled to power supply voltage node. It will be assumed herein that the pulse generator 200 is powered by the VIO power supply voltage but other power supply voltages may also be used in alternative implementations. When the AND gate 205 switches on transistor M1 in response to the assertion of both the POR signal and the delay step signal, the diode connected transistor P1 conducts a current through resistor R1 and transistor M1 to ground. Diode-connected transistor P1 forms a current mirror with a current mirror PMOS transistor P2 that has a source coupled to the power supply voltage node and a gate coupled to the gate of the diode-connected transistor P1. Current mirror transistor P2 will thus conduct a mirrored version of the current conducted by the diode-connected transistor P1. A drain of the current mirror transistor P2 couples to ground through a resistor R2. A voltage will thus develop across resistor R2 in response to assertion of the AND gate 205 output signal. When this voltage reaches the trip point of an inverter 210, the inverter 210 discharges the gate of an NMOS transistor M2. Prior to this trip point, an output signal of the inverter 210 was asserted to the power supply voltage, which maintains transistor M2 on. A drain of the transistor M2 couples to a first terminal of a capacitor C whereas a source of the transistor M2 couples to ground.

A second terminal of the capacitor C couples to ground. Prior to the voltage across the resistor R2 rising to the trip point of the inverter 210, the capacitor C is thus discharged since transistor M2 is on. But as the voltage across resistor R2 rises above the trip point of the inverter 210, transistor M2 switches off. The output of the inverter 210 also drives a PMOS transistor P4 having a drain coupled to the first terminal of the capacitor C. A source of transistor P4 couples to the power supply node through a PMOS current mirror transistor P3. A gate of the current mirror transistor P3 couples to the gate of the diode-connected transistor P1 such that diode-connected transistor P1 and the current mirror transistor P3 form another current mirror. The current conducted by the diode-connected transistor P1 will thus also be mirrored by the current mirror transistor P3 once the voltage across resistor R2 reaches the trip point of the inverter 210 to switch transistor P4 on. A voltage will then begin to develop across capacitor C. A buffer 215 buffers the capacitor voltage to drive a clock input of a latch 220. The operation of the latch 220 will now be discussed in more detail.

The latch 220 is set at the assertion of the POR signal through a pulse circuit 245. The rising edge of the POR signal is delayed through a buffer 230 in pulse circuit 245 and then inverted by an inverter 235. Prior to the rising edge of the POR signal, an output signal of the inverter 235 will thus be asserted. This output signal from the inverter 235 is processed by an AND gate 240 with the POR signal. A set pulse signal produced by the AND gate 240 will thus be asserted by the AND gate 240 in response to the rising edge of the POR signal. After the propagation delay through buffer 230 and inverter 235 is satisfied, the output signal of inverter 235 will discharge, which causes AND gate 240 to discharge the set pulse signal. A pulse width of the set pulse signal will thus be determined by the propagation delay through the buffer 230 and inverter 235. An example pulse width for the set pulse may be a few micro-seconds although a shorter or longer pulse width may be used in alternative implementations. The pulsing of the set pulse signal at the rising edge of the POR signal will thus set the latch 220. The delay step signal that was processed by AND gate 205 is the output signal of the latch 220. The delay step signal will thus be asserted at the rising edge of the POR signal. The delay step signal may also be denoted herein as a latched signal.

The output signal of buffer 215 functions to clock the latch 220. A data (D) input signal to the latch is a grounded (tied to zero, tie0) signal. When the latch 220 is clocked by buffer 215, the latch 220 will thus latch the tie0 signal to cause the delay step signal to be discharged. This discharge of the delay step signal occurs after the voltage across capacitor C rises sufficiently to clock the latch 220. The delay step signal is inverted by an inverter 225 to form a POR delay signal, which is a delayed version of the POR signal. The POR delay signal may also be denoted herein as an inverter output signal. The POR delay signal will thus be asserted after the delay period is satisfied. It will thus be appreciated that by a suitable selection of a resistance for resistor R1 (to minimize current consumption as the diode-connected transistor P1 conducts), the resistance of R2, the relative sizes of the current mirror transistor P2 and P3 with respect to the size of the diode-connected transistor P1, and a capacitance of capacitor C, the delay period between the rising edge of the POR signal and the rising edge of the POR delay signal may be set accordingly. As discussed previously, this delay period should be sufficient to allow the VIO power supply voltage to settle after its ramp-up period. In one example, should the ramp-up period satisfy the MiPi standard of 400 μs, a suitable delay period may be from 500 μs to approximately 1.3 ms but it will be appreciated that the length of the delay period depends upon the expected ramp-up and settling time of the VIO power supply voltage.

At the expiration of the delay period, delay circuit 201 asserts the POR delay signal. This assertion of the POR delay signal then triggers the pulsing of the enable signal. For example, pulse circuit 245 may be duplicated and its propagation delay set accordingly to form an enable pulse circuit 250 that responds to the rising edge of the POR delay signal to pulse the enable signal that activates the VIO detector circuit 110. The VIO detector circuit 110 will thus be activated at the expiration of the delay period and will be de-activated after the on-time (pulse width) of the enable signal. In one example implementation, the delay period may be approximately 500 μs and the pulse width of the enable signal may be approximately 3 μs. In such an implementation, the VIO detector circuit will be activated 500 μs after the assertion of the POR signal and then de-activated 503 μs after the assertion of the POR signal.

Analogous to the implementation of enable pulse circuit 250, the pulse circuit 245 may be duplicated and its propagation delay set accordingly to form a trigger pulse circuit 255 that responds to the rising edge of the POR delay signal to pulse the trigger signal that clocks the latch 115. In one example implementation, the trigger pulse circuit 255 may be configured to pulse the trigger signal for a 1 μs pulse width at 2 μs after the assertion of the POR delay signal. Should the delay period equal 500 μs in such an implementation, the trigger signal would be pulsed starting at 502 μs after the assertion of the POR signal. The VIO detector circuit 110 will now be discussed in more detail.

It will be appreciated the construction of the VIO detector circuit 110 depends upon the magnitude of the high and low levels for the VIO power supply voltage. The following discussion will address an implementation in which the low level is 1.2 V and the high level is 1.8 V but it will be appreciated that the VIO detector circuit 110 is readily modified to distinguish between other voltage levels. The VIO power supply voltage is subject to process, voltage, and temperature variations. Should the integrated circuit 101 be configured to operate with a 1.2 V VIO power supply voltage, the actual VIO power supply voltage could be as high as 1.35 V. Conversely, should the integrated circuit 101 be configured to operate with a 1.8 V VIO power supply voltage, the actual VIO power supply voltage could be a low as 1.6 V. VIO detector circuit 110 may thus be configured to compare the VIO power supply voltage to a suitable threshold voltage such as approximately 1.5 V to distinguish between these two corner conditions for the VIO power supply voltage levels. It is advantageous to generate this threshold by modifying a bandgap reference voltage generator.

An example implementation of the VIO detector circuit 110 is based upon a modified Kuijk cell bandgap reference. In a Kuijk cell bandgap reference, a differential amplifier drives a pair of diodes having different current densities. Because of the current density, a first one of the diodes develops a diode voltage that is received at the non-inverting input of the differential amplifier. It can be shown that such a diode voltage has a complementary-to-absolute-temperature (CTAT) temperature dependency. Given this CTAT behavior, the voltage across this first diode will drop as the temperature increases. Such a variation with temperature is undesirable in a reference voltage as it should be stable despite process, voltage, and temperature variations. A Kuijk cell bandgap reference achieves this stability by balancing the CTAT temperature dependency with a proportional-to-absolute-temperature (PTAT) temperature dependency. Should the CTAT and PTAT dependencies be equal to a first order, the resulting reference voltage is temperature independent to this first order. To achieve this advantageous independence, the second diode in a Kuijk cell bandgap reference is biased at a lower current density than the first diode. The second diode is in series with a pair of resistors with the inverting input to the differential amplifier coupled to a node between the pair of resistors. With the feedback through the differential amplifier functioning to keep the two input terminal voltages equal, it can be shown that the output voltage of the differential amplifier (the reference voltage) in a Kuijk cell bandgap reference has equal (to a first order) PTAT and CTAT dependencies such that it is stable despite temperature variations.

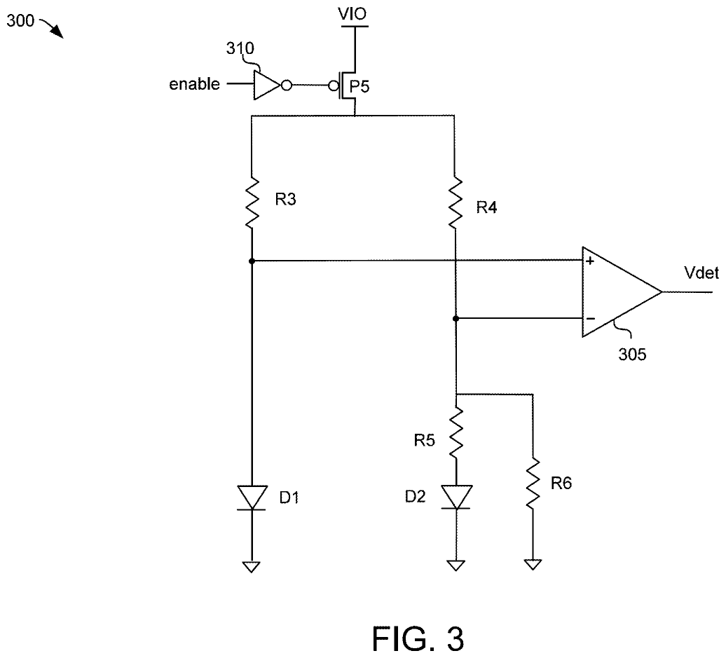

This stable reference voltage of a Kuijk cell bandgap reference is tied to the bandgap voltage of silicon and is thus approximately 1.25V. If the feedback through the differential amplifier is open circuited and the two diode branches driven with a power supply voltage, the output of the differential amplifier may function as the VIO detection signal (Vdet) that would be asserted if the power supply voltage were 1.25V or higher. To produce a VIO detection circuit that would detect whether the power supply voltage has reached a higher voltage such as 1.5V, a modified Kuijk-cell-based is used herein circuit in which a resistor is coupled in parallel with the second diode. As discussed earlier, a threshold voltage for an implementation of the VIO detector circuit 110 to distinguish between 1.2V and 1.8V levels of the VIO power supply voltage should be approximately 1.5V. The modified Kuijk-cell-based VIO detection circuit is thus advantageously adapted herein to function as an implementation 300 of the VIO detector circuit 110 as shown in FIG. 3. The enable signal as inverted through an inverter 310 to drive a gate of a PMOS transistor P5 having a source coupled to a node for the VIO power supply voltage. PMOS transistor P5 functions as a switch that is switched on to activate the VIO detector circuit 110. A drain of transistor P5 couples through a resistor R3 to an anode of a first diode D1 having a cathode coupled to ground. Resistor R3 may also be denoted as a first resistor. The drain of transistor P5 also couples through a serial arrangement of a resistor R4 and a resistor R5 to an anode of a second diode D2 having a cathode coupled to ground. Resistor R4 may also be denoted as a second resistor whereas resistor R5 may also be denoted as a third resistor. Diode D2 may be sized to be N times larger than diode D1 so that there is a lower current density in diode D2 as compared to diode D1, where N is a sufficiently large factor. A comparator 305 receives the anode voltage of the first diode at a non-inverting input terminal. A node between resistors R4 and R5 couples to an inverting input terminal of the differential amplifier 305. The non-inverting input terminal may also be denoted as a first input terminal. Similarly, the inverting input terminal may also be denoted as a second input terminal. Based upon the voltage difference between its input nodes, comparator 305 controls the binary state of the VIO detection signal Vdet. Without more, a threshold voltage for comparator 305 would be 1.25V as discussed for a Kuijk-cell-based POR circuit. In such an implementation, the VIO detection signal Vdet would be charged to the VIO power supply voltage if the VIO power supply voltage was approximately 1.25V or greater. But a resistor R6 couples between the inverting input of the comparator 305 and ground. Resistor R6 may also be denoted as a fourth resistor. The resistor R6 increases the trip point or threshold voltage for the VIO power supply voltage detection to be approximately 1.5V. In this fashion, comparator 305 functions to assert the VIO detection signal Vdet at an output terminal of the comparator 305 in response to the VIO power supply voltage being greater than or equal to approximately 1.5V. Should the VIO power supply voltage be less than this bandgap threshold voltage, comparator grounds the VIO detection signal Vdet. Although such an implementation of VIO detector circuit 110 is advantageously stable with respect to process, voltage, and temperature variations, it will be appreciated that other implementations may also be used.

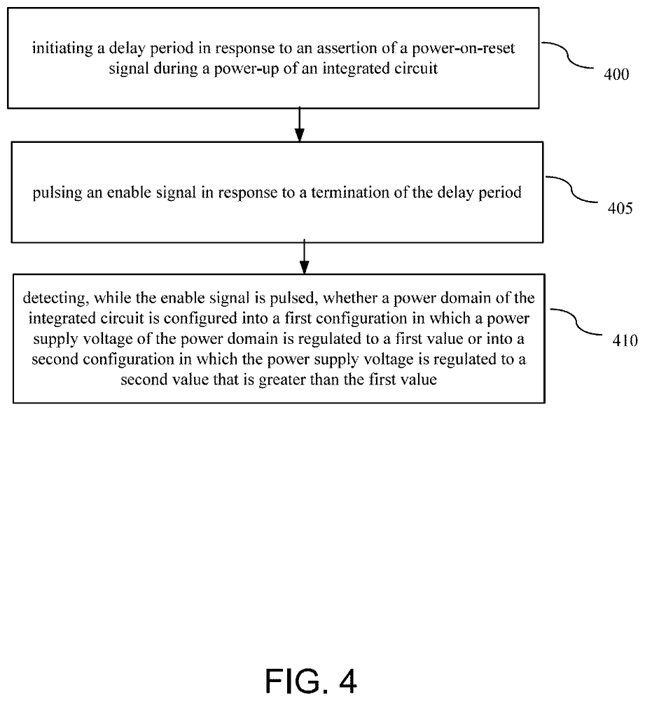

A method of detecting a power supply voltage configuration will now be discussed with respect to the flowchart of FIG. 4. The method includes an act 400 of initiating a delay period in response to an assertion of a power-on-reset signal during a power-up of an integrated circuit. The delay period from the assertion of the POR signal to the assertion of the POR delay signal as instituted by the delay circuit 201 is an example of act 400.

In addition, the method also includes an act 405 of pulsing an enable signal in response to a termination of the delay period. The pulsing of the enable signal by the enable pulse circuit 250 is an example of act 405.

Finally, the method includes an act 410 of detecting, while the enable signal is pulsed, whether a power domain of the integrated circuit is configured into a first configuration in which a power supply voltage of the power domain is regulated to a first value or into a second configuration in which the power supply voltage is regulated to a second value that is greater than the first value. In an example first configuration, the power supply voltage is regulated to equal a low level (e.g., 1.2V although this is merely exemplary. In a second configuration, the power supply is regulated to equal a high level (e.g., 1.8V although this again is merely exemplary). The detection by the VIO detector circuit 110 and the resulting binary value of the VIO detection signal Vdet is an example of act 410. If the VIO detection signal Vdet has a first binary value, then the power domain was configured into the first configuration. Conversely, if the VIO detection signal Vdet has a second binary value that is a complement of the first binary value, then the power domain was configured into the second configuration.

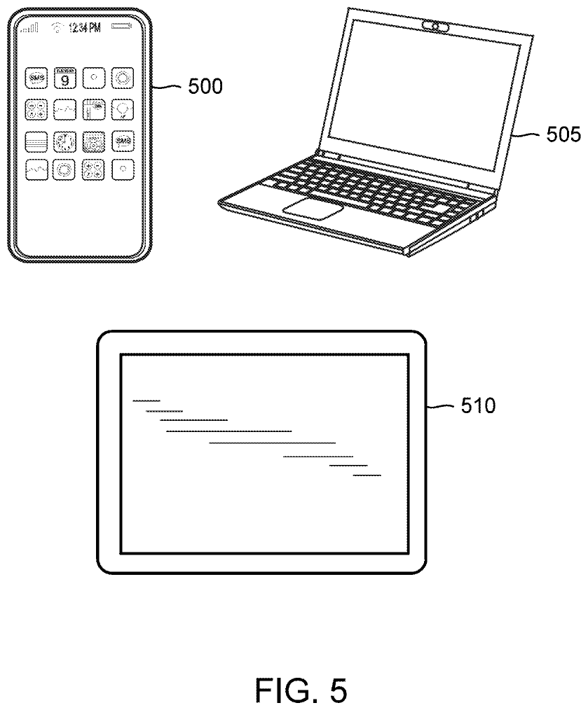

A dual-VIO integrated circuit having a smart start-up detection circuit as disclosed herein may be advantageously employed in a wide variety of electronic systems. For example, as shown in FIG. 5, a cellular telephone 500, a laptop computer 505, and a tablet PC 510 may all include a dual-VIO integrated circuit having a smart start-up detection circuit in accordance with the disclosure. Other exemplary electronic systems such as a music player, a video player, a communication device, and a personal computer may also be configured with a dual-VIO integrated circuit having a smart start-up detection circuit constructed in accordance with the disclosure.

The disclosure will now be summarized in the following series of clauses:

Clause 1. An integrated circuit, comprising:
a delay circuit configured to assert a delay circuit output signal after an expiration of a delay period following an assertion of a power-on reset signal during a power-on of the integrated circuit;
a pulse circuit configured to pulse an enable signal in response to the expiration of the delay period; and
a voltage detection circuit configured to detect, during the pulse of the enable signal, whether a power supply voltage of the integrated circuit is regulated to equal a first value or regulated to equal a second value that is larger than the first value.

Clause 2. The integrated circuit of clause 1, wherein the voltage detection circuit is further configured to set a detection signal to have a first binary value in response to a detection that the power supply voltage is regulated to equal the first value and to have a second binary value that is a complement of the first binary value in response to a detection that the power supply voltage is regulated to equal the second value.

Clause 3. The integrated circuit of clause 2, further comprising:
a latch configured to store the detection signal.

Clause 4. The integrated circuit of clause 2, wherein the voltage detection circuit comprises:
a first diode having a cathode coupled to ground;
a second diode having a cathode coupled to ground;
a first resistor coupled between an anode of the first diode and a node for the power supply voltage;
a comparator having a first input terminal coupled to the anode of the first diode;
a second resistor coupled between the node for the power supply voltage and a second input terminal to the comparator; and
a third resistor coupled between an anode of the second diode and the second input terminal.

Clause 5. The integrated circuit of clause 4, wherein the voltage detection circuit further comprises:
a fourth resistor coupled between the second input terminal and ground.

Clause 6. The integrated circuit of any of clauses 4-5, wherein the first diode is configured to have a higher current density than the second diode.

Clause 7. The integrated circuit of any of clauses 4-6, wherein the comparator is configured to output the detection signal at an output terminal of the comparator.

Clause 8. The integrated circuit of any of clauses 4-7, wherein the voltage detection circuit further comprises:
a switch coupled between the node for the power supply voltage and both the first resistor and the second resistor, wherein the switch is configured to switch on during the pulse of the enable signal.

Clause 9. The integrated circuit of clause 8, wherein the switch comprises a p-type metal-oxide semiconductor (PMOS) transistor.

Clause 10. The integrated circuit of any of clauses 1-9, wherein the delay circuit comprises:
a first transistor;
a logic gate configured to switch on the first transistor responsive to the assertion of the power-on reset signal;
a capacitor;
a current mirror configured to mirror a current conducted by the first transistor into a mirrored current across the capacitor;
a latch configured to latch a grounded signal responsive to being clocked by a voltage across the capacitor to provide a latched signal; and
an inverter configured to invert the latched signal into an inverter output signal that is asserted at the expiration of the delay period.

Clause 11. The integrated circuit of clause 10, wherein the pulse circuit is configured to pulse the enable signal responsive to an assertion of the inverter output signal.

Clause 12. A method of detecting a power supply voltage configuration, comprising:
initiating a delay period in response to an assertion of a power-on-reset signal during a power-up of an integrated circuit;
pulsing an enable signal in response to a termination of the delay period; and
detecting, while the enable signal is pulsed, whether a power domain of the integrated circuit is configured into a first configuration in which a power supply voltage of the power domain is regulated to a first value or into a second configuration in which the power supply voltage is regulated to a second value that is greater than the first value.

Clause 13. The method of clause 12, further comprising:
setting a detection signal to have a first binary value responsive to a detection that the power domain is configured into the first configuration; and
setting the detection signal to have a second binary value that is a complement of the first binary value responsive to a detection that the power domain is configured into the second configuration.

Clause 14. The method of clause 13, further comprising:
adjusting an operating parameter of the integrated circuit responsive to whether the detection signal has the first binary value or the second binary value.

Clause 15. The method of clause 14, wherein adjusting the operating parameter of the integrated circuit comprises adjusting an oscillator frequency.

Clause 16. The method of clause 14, wherein adjusting the operating parameter of the integrated circuit comprises adjusting a timing of a digital circuit.

Clause 17. A multi-voltage input/output (VIO) integrated circuit, comprising:
a delay circuit configured to delay a power-on reset signal to produce a delayed version of the power-on reset signal; and
a VIO detection circuit configured to assert a VIO detection signal responsive to a power supply voltage of a VIO power domain in the integrated circuit being greater than a threshold voltage.

Clause 18. The integrated circuit of clause 17, further comprising:
a latch configured to latch the VIO detection signal.

Clause 19. The integrated circuit of any of clauses 17-18, wherein the integrated circuit is included within a cellular telephone.

Clause 20. The integrated circuit of any of clauses 17-19, wherein the integrated circuit is configured to adjust an operating parameter responsive to a binary value of the VIO detection signal.

Clause 21. The integrated circuit of any of clauses 17-20, further comprising:
a pulse circuit configured to pulse an enable signal responsive to an assertion of the delayed version of the power-on reset signal, wherein the VIO detection circuit is configured to be activated only while the enable signal is pulsed.

Clause 22. The integrated circuit of any of clauses 17-21, wherein the threshold voltage is a bandgap reference voltage.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. An integrated circuit, comprising:
a delay circuit configured to assert a delay circuit output signal after an expiration of a delay period following an assertion of a power-on reset signal during a power-on of the integrated circuit;
a pulse circuit configured to pulse an enable signal in response to the expiration of the delay period; and
a voltage detection circuit configured to detect, during the pulse of the enable signal, whether a power supply voltage of the integrated circuit is regulated to equal a first value or regulated to equal a second value that is larger than the first value.

2. The integrated circuit of claim 1, wherein the voltage detection circuit is further configured to set a detection signal to have a first binary value in response to a detection that the power supply voltage is regulated to equal the first value and to have a second binary value that is a complement of the first binary value in response to a detection that the power supply voltage is regulated to equal the second value.

3. The integrated circuit of claim 2, further comprising:
a latch configured to store the detection signal.

4. The integrated circuit of claim 2, wherein the voltage detection circuit comprises:
a first diode having a cathode coupled to ground;
a second diode having a cathode coupled to ground;
a first resistor coupled between an anode of the first diode and a node for the power supply voltage;
a comparator having a first input terminal coupled to the anode of the first diode;
a second resistor coupled between the node for the power supply voltage and a second input terminal to the comparator; and
a third resistor coupled between an anode of the second diode and the second input terminal.

5. The integrated circuit of claim 4, wherein the voltage detection circuit further comprises:
a fourth resistor coupled between the second input terminal and ground.

6. The integrated circuit of claim 4, wherein the first diode is configured to have a higher current density than the second diode.

7. The integrated circuit of claim 4, wherein the comparator is configured to output the detection signal at an output terminal of the comparator.

8. The integrated circuit of claim 4, wherein the voltage detection circuit further comprises:
a switch coupled between the node for the power supply voltage and both the first resistor and the second resistor, wherein the switch is configured to switch on during the pulse of the enable signal.

9. The integrated circuit of claim 8, wherein the switch comprises a p-type metal-oxide semiconductor (PMOS) transistor.

10. The integrated circuit of claim 1, wherein the delay circuit comprises:
a first transistor;
a logic gate configured to switch on the first transistor responsive to the assertion of the power-on reset signal;
a capacitor;
a current mirror configured to mirror a current conducted by the first transistor into a mirrored current across the capacitor;
a latch configured to latch a grounded signal responsive to being clocked by a voltage across the capacitor to provide a latched signal; and
an inverter configured to invert the latched signal into an inverter output signal that is asserted at the expiration of the delay period.

11. The integrated circuit of claim 10, wherein the pulse circuit is configured to pulse the enable signal responsive to an assertion of the inverter output signal.

12. A method of detecting a power supply voltage configuration, comprising:
initiating a delay period in response to an assertion of a power-on-reset signal during a power-up of an integrated circuit;
pulsing an enable signal in response to a termination of the delay period; and
detecting, while the enable signal is pulsed, whether a power domain of the integrated circuit is configured into a first configuration in which a power supply voltage of the power domain is regulated to a first value or into a second configuration in which the power supply voltage is regulated to a second value that is greater than the first value.

13. The method of claim 12, further comprising:
setting a detection signal to have a first binary value responsive to a detection that the power domain is configured into the first configuration; and
setting the detection signal to have a second binary value that is a complement of the first binary value responsive to a detection that the power domain is configured into the second configuration.

14. The method of claim 13, further comprising:
adjusting an operating parameter of the integrated circuit responsive to whether the detection signal has the first binary value or the second binary value.

15. The method of claim 14, wherein adjusting the operating parameter of the integrated circuit comprises adjusting an oscillator frequency.

16. The method of claim 14, wherein adjusting the operating parameter of the integrated circuit comprises adjusting a timing of a digital circuit.

17. A multi-voltage input/output (VIO) integrated circuit, comprising:
a delay circuit configured to delay a power-on reset signal to produce a delayed version of the power-on reset signal; and
a VIO detection circuit configured to assert a VIO detection signal responsive to a power supply voltage of a VIO power domain in the integrated circuit being greater than a threshold voltage.

18. The integrated circuit of claim 17, further comprising:
a latch configured to latch the VIO detection signal.

19. The integrated circuit of claim 17, wherein the integrated circuit is included within a cellular telephone.

20. The integrated circuit of claim 17, wherein the integrated circuit is configured to adjust an operating parameter responsive to a binary value of the VIO detection signal.

21. The integrated circuit of claim 17, further comprising:
a pulse circuit configured to pulse an enable signal responsive to an assertion of the delayed version of the power-on reset signal, wherein the VIO detection circuit is configured to be activated only while the enable signal is pulsed.

22. The integrated circuit of claim 17, wherein the threshold voltage is a bandgap reference voltage.
